(19) United States
(12) Patent Application Publication
(10) Pub. No.: US 2019/0326559 A1
(43) Pub. Date: Oct. 24, 2019

(54) METHOD OF FORMING PATTERN USING SUPRAMOLECULAR NANOSTRUCTURES

(71) Applicant: KOREA ADVANCED INSTITUTE OF SCIENCE AND TECHNOLOGY, Daejeon (KR)

(72) Inventors: Hee-Tae JUNG, Daejeon (KR); Kangho Park, Daejeon (KR); Woo-Bin Jung, Daejeon (KR); Kiok Kwon, Daejeon (KR)

(73) Assignee: KOREA ADVANCED INSTITUTE OF SCIENCE AND TECHNOLOGY, Daejeon (KR)

(21) Appl. No.: 16/197,531

(22) Filed: Nov. 21, 2018

(30) Foreign Application Priority Data
Apr. 20, 2018 (KR) 10-2018-0046199

(51) Int. Cl. H01L 51/56; H01L 51/00; H01P 11/00; C08L 101/00

(52) U.S. Cl. CPC H01L 51/56; H01L 51/0014; H01L 2251/105; H01P 11/001; C08L 101/005; H01L 51/0012

(57) ABSTRACT

According to the present disclosure, a method of forming a pattern may include forming guide patterns on a substrate, wherein a trench is provided between the guide patterns, forming an organic-inorganic pattern including organic supramolecular structures in the trench, and annealing the organic-inorganic pattern, thereby aligning the dendrimer structures in parallel with one direction.

### CROSS-REFERENCE TO RELATED APPLICATIONS

This U.S. non-provisional patent application claims priority under 35 U.S.C. § 119 of Korean Patent Application No. 10-2018-0046199, filed on Apr. 20, 2018, the entire contents of which are hereby incorporated by reference.

### BACKGROUND

The present disclosure herein relates to a method of forming a pattern, and more particularly, to method of forming a pattern using dendrimer molecules.

Formation of nanostructures by self-assembly of soft material molecules such as colloids, block copolymers, surfactants, supramolecules or the like has been studied for a long time.

Soft material molecules are capable of forming various and new nanostructures due to the structure, shape, interactions, or the like of themselves, and the use of the above nanostructures allows the development of effective nano-patterning technologies.

Studies on the formation of nanostructures using block copolymers among such soft material molecules have been most actively proceeded. However, in current technologies, a process of embodying ordered structures over large areas is complex and requires a long time (a few hours), and thus there is a limitation in terms of commercial applications.

### SUMMARY

The present disclosure provides an organic-inorganic pattern including aligned organic supramolecular structures with a large area and a forming method thereof.

However, the present disclosure is not limited thereto and other objects not mentioned can be clearly understood by those skilled in the art from the following description.

The present disclosure relates to method of forming a pattern.

An embodiment of the inventive concept provides a method of forming a pattern, including: forming guide patterns on a substrate, wherein a trench is provided between the guide patterns; forming an organic-inorganic pattern including organic supramolecular structures in the trench; and annealing the organic-inorganic pattern, thereby aligning the organic supramolecular structures in parallel with one direction.

In an embodiment, the organic supramolecular structures, before the annealing the organic-inorganic pattern, may include: a first organic supramolecular structure arranged in parallel with a first direction; and a second organic supramolecular structure arranged in parallel with a second direction.

In an embodiment, the aligning the organic supramolecular structures in parallel with one direction may include arranging the second organic supramolecular structure in parallel with the first direction.

In an embodiment, the guide patterns may extend in parallel with the one direction.

In an embodiment, the height of the organic-inorganic pattern may be 0.1 nm to 1 μm, and the organic-inorganic pattern may be at least 0.001 times and less than 1 times higher than the guide patterns.

In an embodiment, the organic supramolecular structures may include dendrimer molecules.

In an embodiment, the guide patterns may extend in parallel with the other direction and the other direction may be perpendicular to the one direction.

In an embodiment, the organic-inorganic pattern may be at least 1 times and less than 1.5 times higher than the guide patterns.

In an embodiment, the guide patterns may include a material different from the substrate, and the trench may expose an upper surface of the substrate.

In an embodiment, the forming guide patterns may include removing a part of the substrate, thereby forming trenches, and the guide patterns may include the same material as the substrate.

In an embodiment, the forming the organic-inorganic pattern may include: preparing an organic solution including dendrimer molecules; and applying the organic solution into the trench.

### BRIEF DESCRIPTION OF THE FIGURES

For a more complete understanding and assistance of the present disclosure, reference is made to the following description, taken in conjunction with the accompanying drawings and reference numerals are shown below.

FIG. 1 is a view for describing an organic supramolecular domain according to embodiments.

FIGS. 2A to 2C are perspective views illustrating a method for manufacturing an organic-inorganic pattern according to embodiments of the inventive concept.

FIGS. 3A and 3B are perspective views illustrating a method for manufacturing a pattern according to other embodiments.

FIGS. 4A and 4B are perspective views illustrating a method for manufacturing an organic-inorganic pattern according to another embodiments.

FIGS. 5A to 5C are perspective views illustrating a method for manufacturing an organic-inorganic pattern according to another embodiments.

FIG. 5D is a perspective view illustrating the organic-inorganic pattern manufactured according to another embodiments.

FIG. 5E is a perspective view illustrating the organic-inorganic pattern manufactured according to another embodiments.

FIG. 6 is a graph showing the alignment direction of organic supramolecular structures of the organic-inorganic pattern depending on the widths between the guide patterns and the heights of the guide patterns.

### DETAILED DESCRIPTION

In order to fully understand the feature and effect of the present disclosure, preferred embodiments of the inventive concept will be described with reference to the accompanying drawings. However, the present disclosure is not limited to embodiments disclosed below, but may be implemented in many different forms and various changes may be added thereto. Rather, these embodiments are provided through the description of the embodiments so that this disclosure will be complete, and will fully convey the scope of the inventive concept to those skilled in the art. Those skilled in the art will appreciate that the inventive concept may be practiced in any suitable environment.

The terminology used herein is for the purpose of describing embodiments only and is not intended to be limiting of the present disclosure. As used herein, the singular forms, “a”, “an” and “the” are intended to include the plural forms as well, unless the context clearly indicates otherwise. The terms “includes” and/or “including” when used in this specification, specify the presence of stated components, steps, operations, and/or elements, but do not preclude the presence or addition of one or more other components, steps, operations, and/or elements.

In this specification, when a film (or layer) is referred to as being ‘on’ another film (or layer) or substrate, it can be formed directly on the other film (or layer) or substrate, or a third film (or layer) may also be interposed therebetween.

Although the terms first, second, third, etc. are used in various embodiments of the inventive concept to describe various regions, films (or layers), etc., these regions, films should not be limited by these terms. These terms are only used to distinguish a specific region or film (or layer) from another region or film (or layer). Therefore, in any one embodiment the film quality referred to as a first film quality may be referred to as a second film quality in another embodiment. Each embodiment described and illustrated herein includes its complementary embodiments.

Unless otherwise defined, the terms used in embodiments of the inventive concept may be interpreted as having the same meaning as commonly understood by one of ordinary skill in the art.

In this specification, like reference numerals may refer to like elements throughout.

Organic supramolecular structures according to an embodiment of the inventive concept and a method for forming an organic-inorganic pattern using the same will be described.

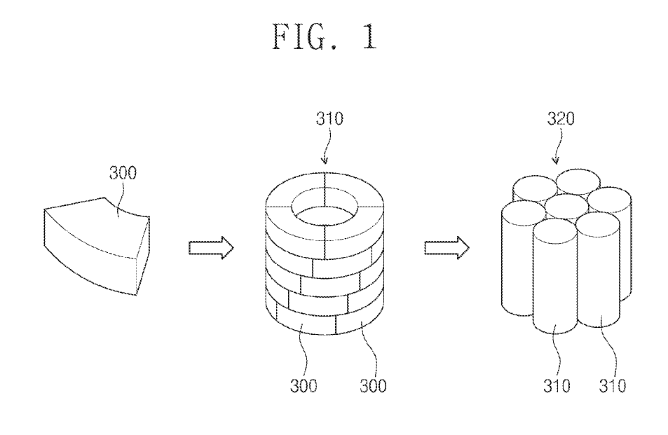

FIG. 1 is a view for describing an organic supramolecular domain according to embodiments.

Referring to FIG. 1, the organic supramolecules may be self-assembled to form the organic supramolecular domain 320. Dendrimer molecules may be used as the organic supramolecules. A dendrimer molecule is a macromolecule having a regular branched structure, which may contain a plurality of repeated branching cycles by synthesis. The dendrimer molecule may be represented by Formula 1 or Formula 2 below, but is not limited thereto.

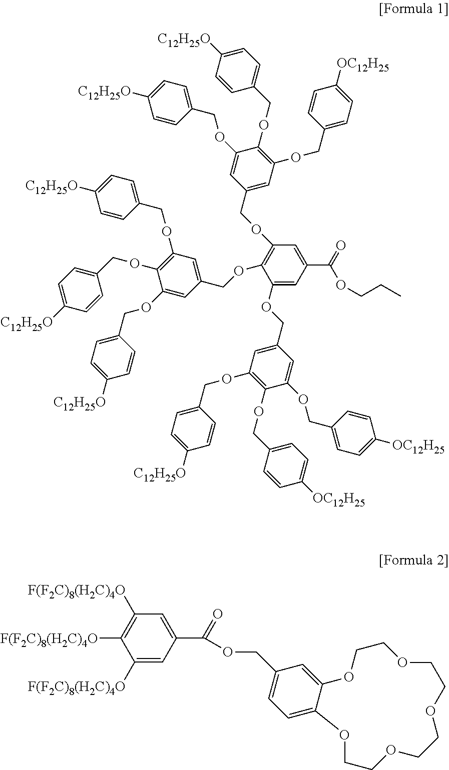

The organic supramolecule may be prepared plurally. The organic supramolecules may form the preliminary structure 300 by intermolecular interaction between themselves. The intermolecular interaction may be van der Waals attraction. Accordingly, the preliminary structure 300 may include a plurality of the organic supramolecules. The preliminary structure 300 may be formed plurally.

The organic supramolecular structure 310 may be formed by the interaction between the preliminary structures 300. The organic supramolecular structure 310 may be columnar (e.g., cylindrical) in shape. The organic supramolecular structure 310 may be formed plurally. The diameters of the organic supramolecular structures 310 may be approximately 4.7 nm, but are not limited thereto.

The organic supramolecular structures 310 may interact with each other. The organic supramolecular structures 310 may form the organic supramolecular domain 320 by the interaction between themselves. The organic supramolecular domain 320 may include a plurality of the organic supramolecular structures 310. The organic supramolecular domain 320 may have a hexagonal packing structure in a plan view. The organic supramolecular domain 320 may be spontaneously formed from organic supramolecular structures 310. Each of the organic supramolecular structures 310 included in the organic supramolecular domain 320 may be aligned in one direction. In this specification, the alignment direction of the organic supramolecular domain 320 may mean the directions of the major axes of the organic supramolecular structures 310 constituting the organic supramolecular domain 320.

Hereinafter, a method of manufacturing the organic/inorganic pattern according to an embodiment of the inventive concept will be described.

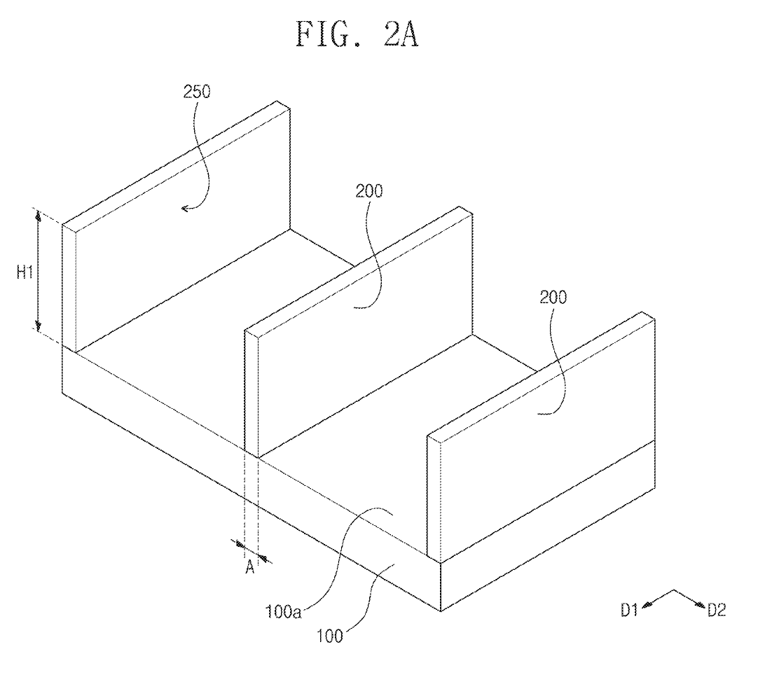

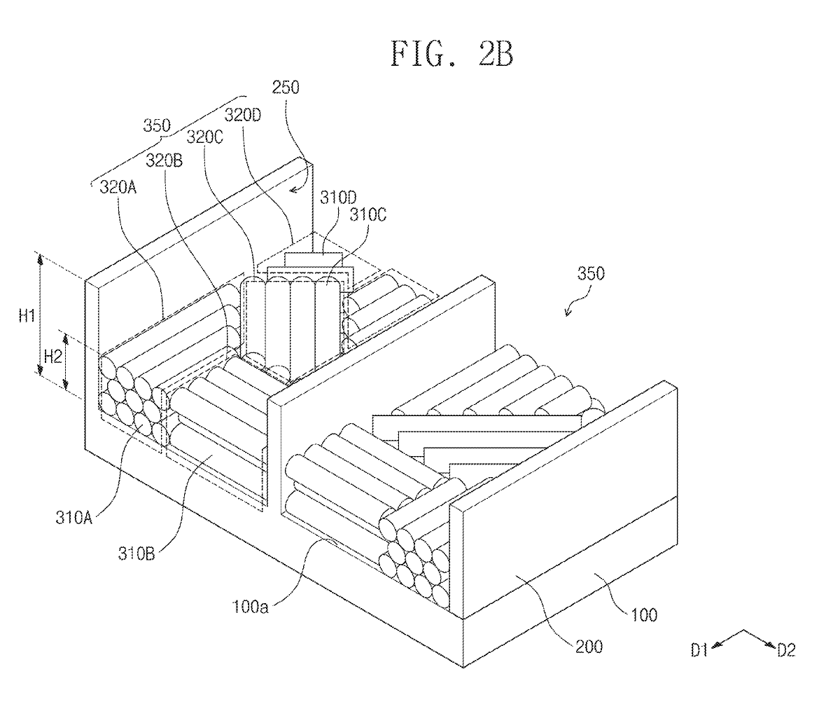

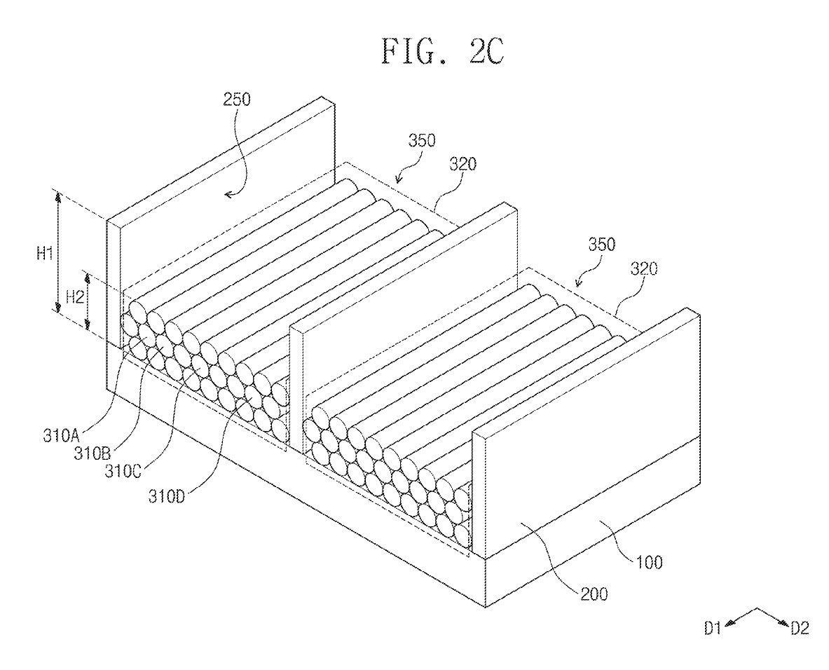

FIGS. 2A to 2C are perspective views illustrating a method for manufacturing an organic-inorganic pattern according to embodiments of the inventive concept. Hereinafter, the contents overlapping with those described above will be omitted.

Referring to FIG. 2A, the guide patterns 200 may be formed on the substrate 100. As one example, the substrate 100 may include an inorganic material such as silicone or glass. As another example, the substrate 100 may include an organic material such as plastic or polymer.

The guide patterns 200 may be formed on an upper surface 100a of the substrate 100. The guide patterns 200 may include a material different from the substrate 100. As one example, the guide patterns 200 may include a metal such as gold (Au). The guide patterns 200 may extend in parallel with the first direction D1. For example, each of the guide patterns 200 may have a major axis parallel to a first direction D1. The guide patterns 200 may have a high aspect ratio. For example, a height H1 of the each guide pattern 200 may be greater than a width A of the guide pattern 200. The guide patterns 200 may be spaced apart from each other in a second direction D2. Herein, the first direction D1 and the second direction D2 may be parallel to the upper surface 100a of the substrate 100. The second direction D2 may be substantially perpendicular to the first direction D1. In this specification, “perpendicular to” includes the margin of error that may occur in a process. The trench 250 may be provided between the guide patterns 200. The trench 250 may expose the upper surface 100a of the substrate 100. The trench 250 may extend along the first direction D1. The guide patterns 200 may be formed by secondary sputtering lithography method, but the formation method is not limited.

Referring to FIG. 2B, the organic-inorganic pattern 350 may be formed on the substrate 100. The organic-inorganic pattern 350 may be provided in the trench 250 between the guide patterns 200. According to embodiments, organic supramolecules may be added to a solvent so as to prepare an organic solution. As an example, chloroform or water may be used as the solvent. The organic supramolecules may be dendrimer molecules represented by the Formula 1 or Formula 2 above, but are not limited thereto. The organic solution may be applied onto the substrate 100 so as to form the organic-inorganic pattern 350. Herein, a drying process may be carried out over the organic-inorganic pattern 350, so that the solvent in the organic-inorganic pattern 350 is removed. A height H2 of the organic-inorganic pattern 350 may be smaller than the height H1 of the guide patterns. The height H2 of the organic-inorganic pattern 350 may be at least 0.001 times and less than 1 times greater than the height H1 of the guide patterns. The height H2 of the organic-inorganic pattern 350 may be 0.1 nm to 1 μm.

The organic-inorganic pattern 350 may include the first organic supramolecular domain 320A, the second organic supramolecular domain 320B, the third organic supramolecular domain 320C, and the fourth organic supramolecular domain 320D. According to embodiments, the organic supramolecules may spontaneously form the organic supramolecular domains 320A, 320B, 320C, and 320D as described above with reference to FIG. 1. The organic supramolecular domains 320A, 320B, 320C, and 320D may be randomly arranged. The first organic supramolecular domain 320A may include the first organic supramolecular structures 310A. The first organic supramolecular structures 310A may be arranged in parallel with the first direction D1. The second organic supramolecular domain 320B may include the second organic supramolecular structures 310B arranged in parallel with the second direction D2. The third organic supramolecular domain 320C may include the third organic supramolecular structures 310C arranged in parallel with a third direction. The third direction may be different from the first direction D1 and the second direction D2. The fourth organic supramolecular domain 320D may include the fourth organic supramolecular structures 310D arranged in parallel with a fourth direction. The fourth direction may be different from the first direction D1, the second direction D2, and the third direction. Although not shown, the organic-inorganic pattern 350 may further include a fifth organic supramolecular domain.

Referring to FIG. 2C, an annealing process may be carried out over the organic-inorganic pattern 350 so that the organic supramolecular structures 310A, 310B, 310C, and 310D are aligned in one direction. The annealing process may include increasing the fluidity of the organic supramolecular structures 310A, 310B, 310C, and 310D, and reducing the increased fluidity of the organic supramolecular structures 310A, 310B, 310C, and 310D. During the process of reducing the fluidity of the organic supramolecular structures 310A, 310B, 310C, and 310D, the organic supramolecular structures 310A, 310B, 310C, and 310D may be aligned in one direction by the interaction between themselves. For example, the first organic supramolecular structures 310A, the second organic supramolecular structures 310B, the third organic supramolecular structures 310C, and the fourth organic supramolecular structures 310D may be arranged in one direction (e.g., in the first direction D1) by the annealing process. Accordingly, the organic-inorganic pattern 350 may include the single organic supramolecular domain 320, and the single organic supramolecular domain 320 may be aligned in the first direction D1. The height H2 of the organic-inorganic pattern 350 may be 0.1 nm to 1 μm. When the height H2 of the organic-inorganic pattern 350 is less than 1 times greater than the height H1 of the guide patterns 200 (that is, the height H2 of the organic-inorganic pattern 350 is smaller than the height H1 of the guide patterns 200), the interface between the organic-inorganic pattern 350 and air may not be flat. In this case, after the annealing process, the organic supramolecular structures 310A, 310B, 310C, and 310D aligned in the first direction D1 may have low elastic energy rather than that of the organic supramolecular structures 310A, 310B, 310C, and 310D aligned in the second direction. Accordingly, the organic supramolecular structures 310A, 310B, 310C, and 310D may be aligned in the first direction D1. Herein, the first direction D1 may correspond to the major axis direction of each of guide patterns 200 as described above.

The annealing process may include thermal annealing or solvent annealing. The thermal annealing process may proceed under conditions same temperature or higher temperature than an isotropic phase transition temperature of the organic supramolecules. The isotropic phase transition temperature of the organic supramolecules may be a temperature at which the organic supramolecules are randomly arranged so as to have fluidity. For example, if the organic supramolecular structures 310A, 310B, 310C, and 310D and the organic supramolecular domains 320A, 320B, 320C, and 320D are provided under conditions same or higher than an isotropic phase transition temperature, the organic supramolecular structures 310A, 310B, 310C and 310D and the organic supramolecular domains 320A, 320B, 320C and 320D may be removed and the organic supramolecules may be randomly arranged. As an example, the thermal annealing process may be performed at the temperature condition of 87° C. to 150° C. If the thermal annealing process proceeds at a temperature lower than the isotropic temperature (e.g., 87° C.) of the organic supramolecules, it is difficult that each of the organic supramolecular structures 310A, 310B, 310C and 310D are aligned in one direction. If the thermal annealing process proceeds under excessively high temperature conditions (e.g., above 150° C.), the organic supramolecules may be damaged. Thereafter, the organic-inorganic pattern 350 may be cooled down to room temperature (e.g., about 25° C.). The cooling of the organic-inorganic pattern 350 may proceed at the cooling rate of 5° C./min or less. When the cooling rate of the organic-inorganic pattern 350 is greater than 5° C./min, it is difficult that the organic supramolecular structures 310A, 310B, 310C and 310D are hardly aligned. As another example, the annealing process may include a solvent annealing process. In this case, the drying process of FIG. 2B may not be performed. The solvent annealing process may be carried out by evaporating the solvent in the organic-inorganic pattern 350.

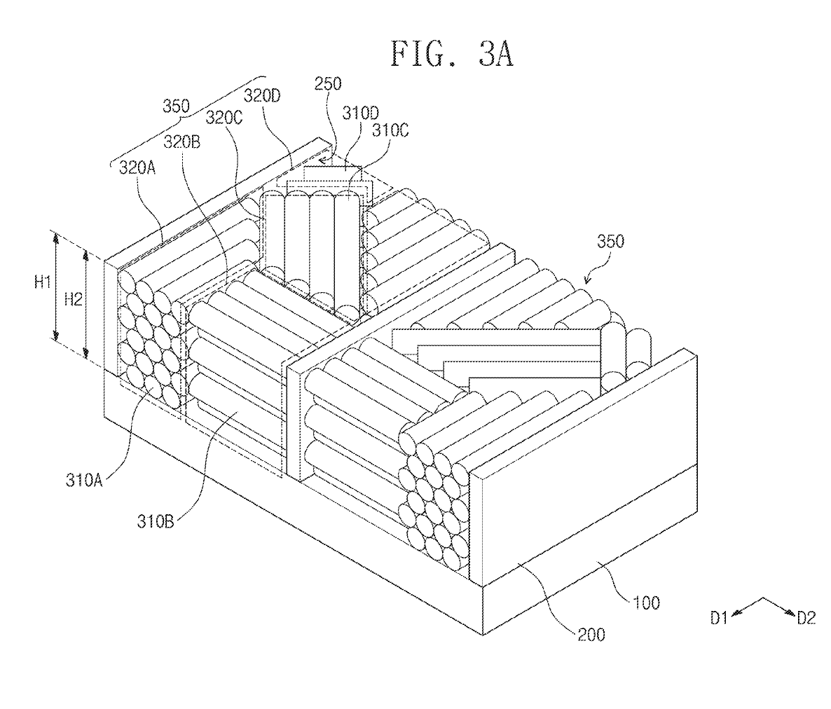

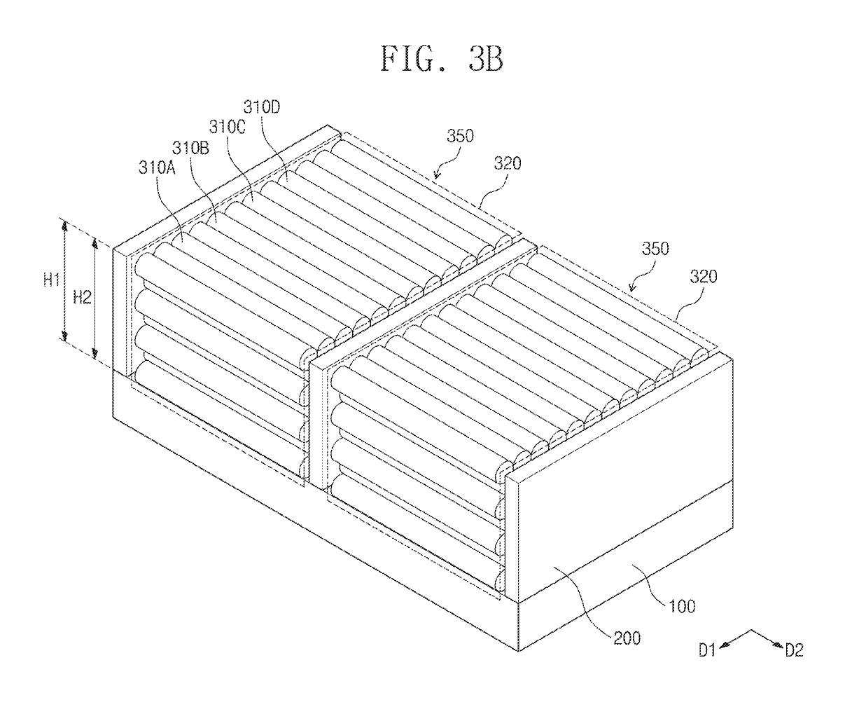

FIGS. 3A and 3B are perspective views illustrating a method for manufacturing a pattern according to other embodiments. Hereinafter, the contents overlapping with those described above will be omitted.

Referring to FIG. 3A, the guide patterns 200 may be formed on the substrate 100. The organic-inorganic pattern 350 may be formed in the trench 250. The substrate 100, the guide patterns 200, and the organic-inorganic pattern 350 may be substantially the same as those described above with reference to FIG. 2A. For example, the organic-inorganic pattern 350 may include the organic supramolecular structures 310A, 310B, 310C, and 310D, and the organic supramolecular structures 310A, 310B, 310C, and 310D may be arranged in directions different from each other. However, the height H2 of the organic-inorganic pattern 350 may be 1 to 1.5 times greater than the height H1 of the guide patterns.

Referring to FIG. 3B, the annealing process may be carried out over the organic-inorganic pattern 350 so that the organic supramolecular structures 310A, 310B, 310C, and 310D are aligned in one direction. Accordingly, the organic-inorganic pattern 350 may include the single organic supramolecular domain 320. Herein, the one direction may be the second direction D2. According to an embodiment, when the height H2 of the organic-inorganic pattern 350 is 1 to 1.5 times greater than the height H1 of the guide patterns, the alignment direction of the organic supramolecular structures 310A, 310B, 310C, and 310D may be determined by the anchoring effect by the physical surfaces of the guide patterns 200 (e.g., the side surfaces of the guide patterns 200). Accordingly, the organic supramolecular structures 310A, 310B, 310C, and 310D may be aligned in the second direction D2. The annealing may be performed by the same method as described with reference to FIG. 2C.

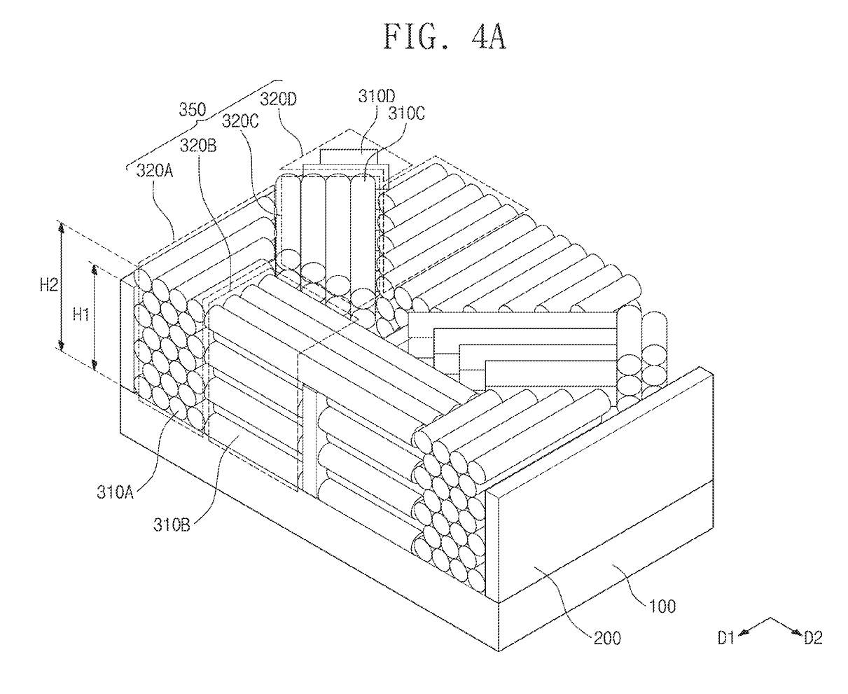

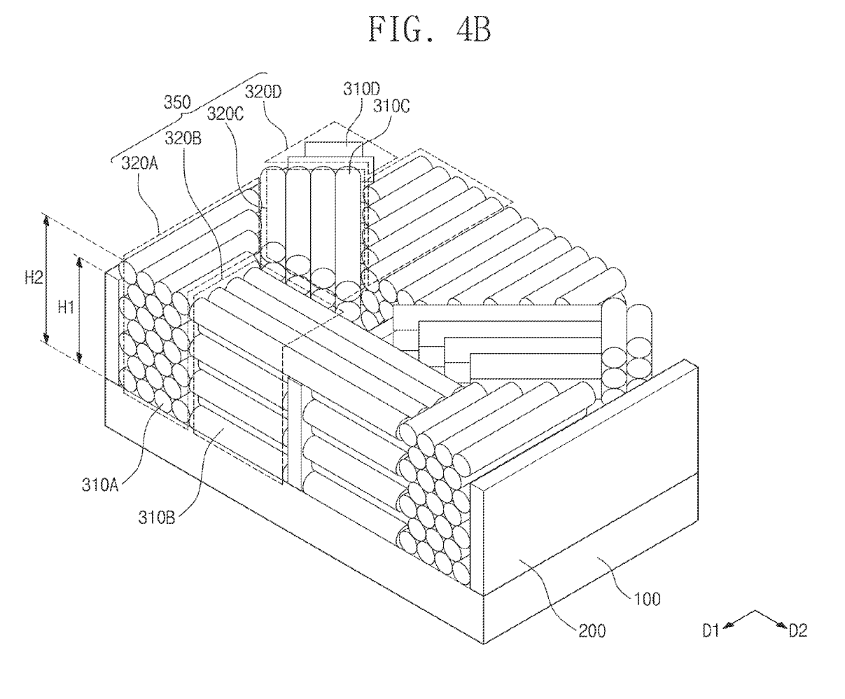

FIGS. 4A and 4B are perspective views illustrating a method for manufacturing an organic-inorganic pattern according to another embodiments. Hereinafter, the contents overlapping with those described above will be omitted.

Referring to FIG. 4A, the guide patterns 200 may be formed on the substrate 100. The organic-inorganic pattern 350 may be formed in the trench 250. The substrate 100, the guide patterns 200, and the organic-inorganic pattern 350 may be substantially the same as those described above with reference to FIG. 2A. However, the height H2 of the organic-inorganic pattern 350 may 1.5 times greater than the height H1 of the guide patterns 200.

Referring to FIG. 4B, the annealing process may be carried out over the organic-inorganic pattern 350. Unlike FIGS. 2C and 3D, after the annealing process, the organic supramolecular structures 310A, 310B, 310C, and 310D may not be aligned in one direction. The organic supramolecular domains 320A, 320B, 320C, and 320D may be randomly arranged.

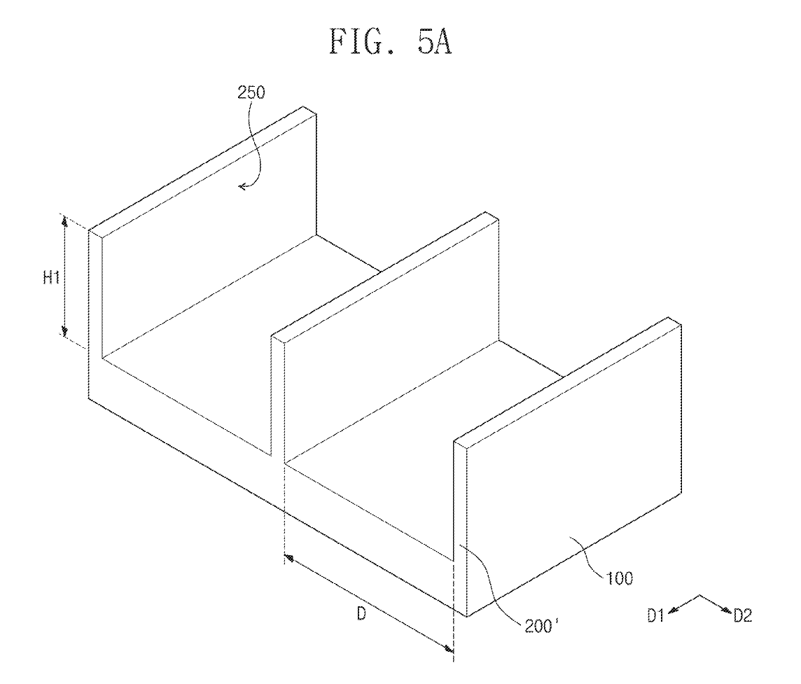

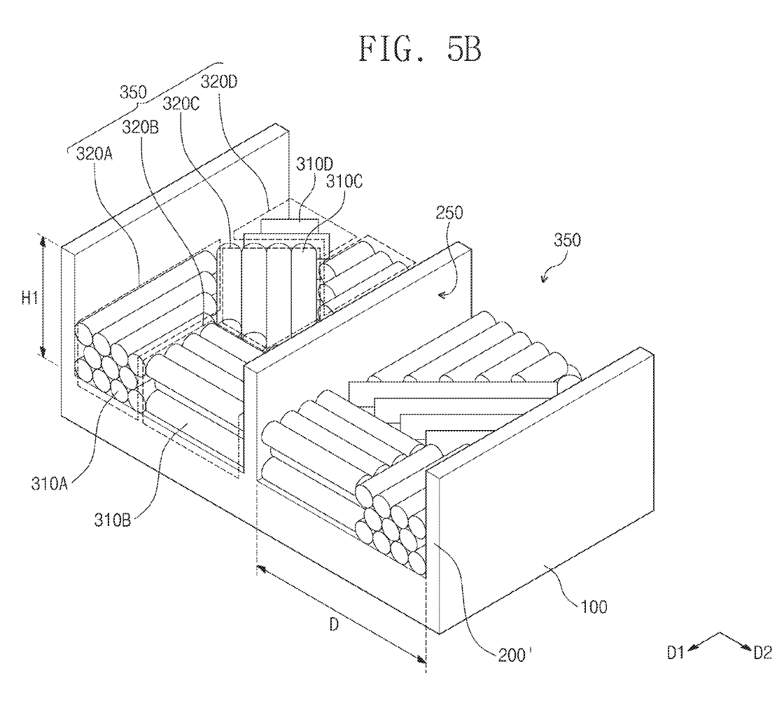

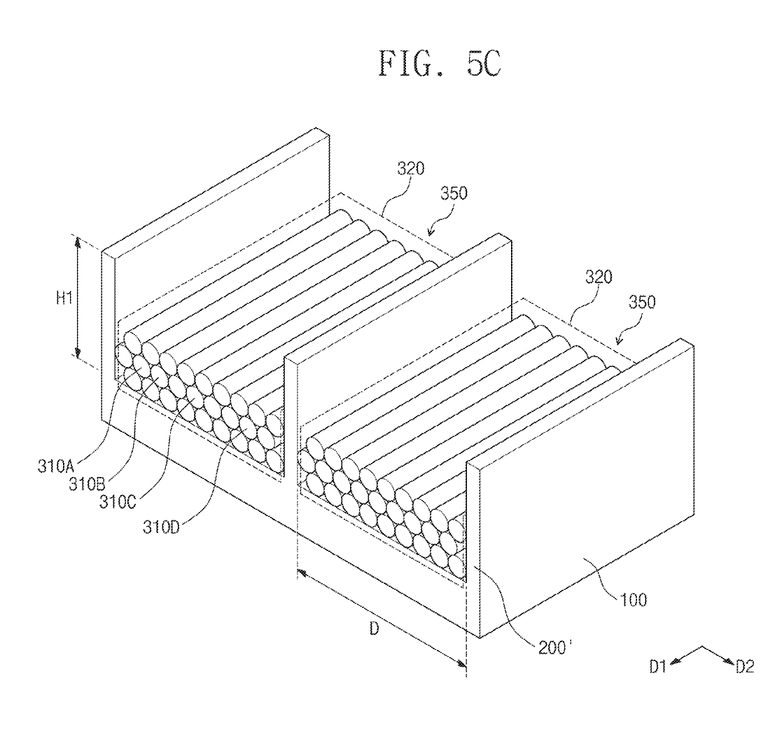

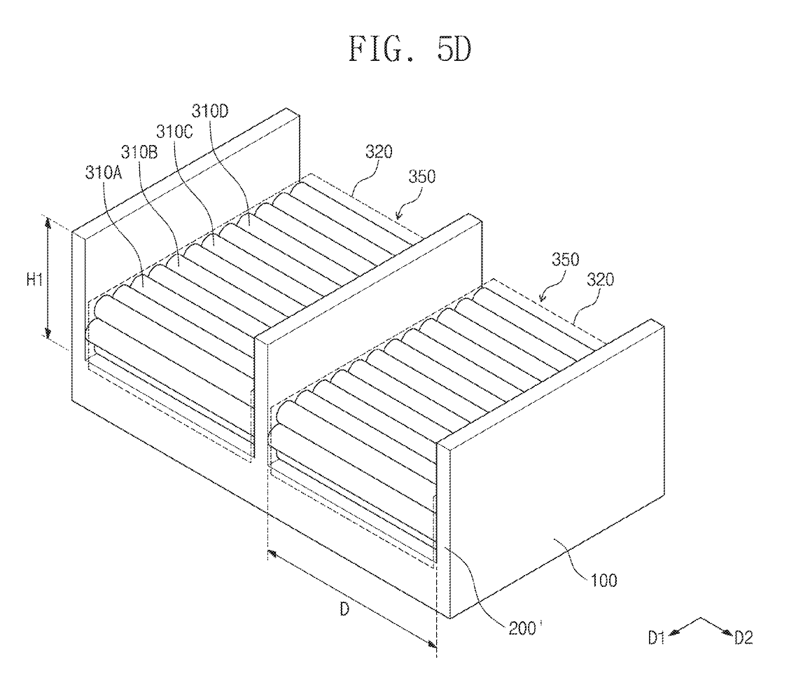

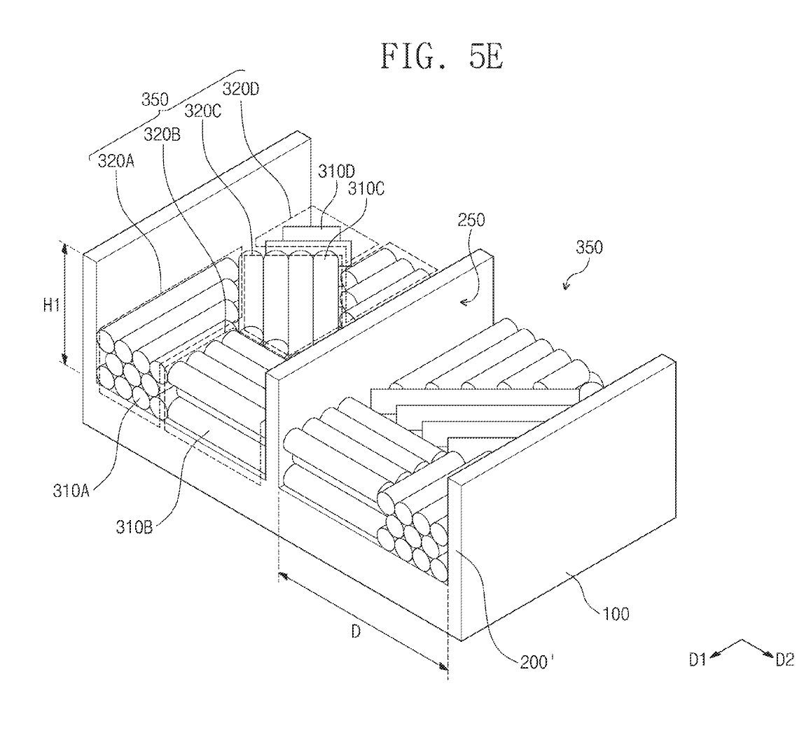

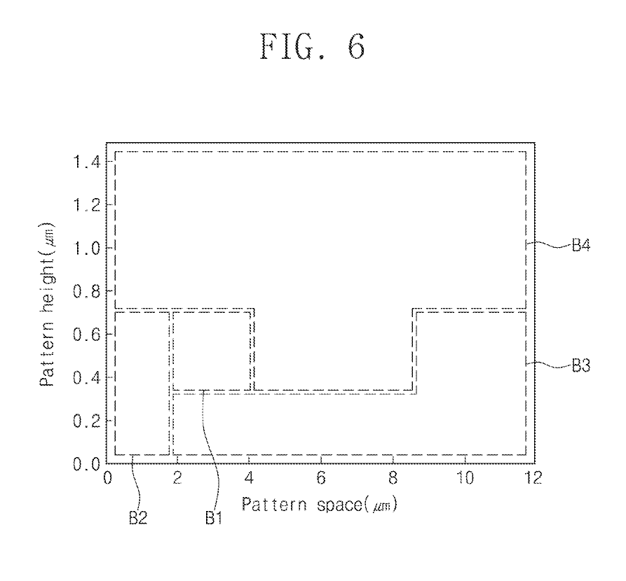

FIGS. 5A to 5C are perspective views illustrating a method for manufacturing an organic-inorganic pattern according to another embodiments. FIG. 6 is a graph showing the alignment direction of organic supramolecular structures of the organic-inorganic pattern according to the widths between the guide patterns and the heights of the guide patterns and shows the alignment direction of the organic-inorganic pattern manufactured by using the guide pattern 200 in FIG. 5A.

Referring to FIG. 5A, the guide patterns 200′ may be formed on the substrate 100. The substrate 100 may include silicone, but the material of the substrate 100 is not limited thereto. The guide patterns 200′ may be formed integrally with the substrate 100. For example, the guide patterns 200′ may be connected to the substrate 100 without an interface. The formation of the guide patterns 200′ may include forming the trench 250 on one surface of the substrate 100. The trench 250 may be formed by removing a part of the substrate 100. The major axes of the guide patterns 200′ and the trench 250 may extend in the first direction D1.

Referring to FIG. 5B, the organic-inorganic pattern 350 may be formed in the trench 250. The organic-inorganic pattern 350 may be formed by the same method as described above with reference to FIG. 2B. The organic supramolecular domains 320A, 320B, 320C, and 320D of the organic-inorganic pattern 350 may have a random arrangement. The second to the fourth organic supramolecular structures 310B, 310C, and 310D may not be aligned in one direction.

Referring to FIGS. 5C and 6, the annealing process may be carried out over the organic-inorganic pattern 350 so that the organic supramolecular structures 310A, 310B, 310C, and 310D are aligned. Accordingly, the organic-inorganic pattern 350 may include the single organic supramolecular domain 320. The annealing may be performed by the same method as described above with reference to FIG. 2C. The distance D between the guide patterns 200′ may be more than 2 μm and 4 μm or less and the heights H1 of the guide patterns 200′ may be more than 0.35 μm and 0.7 μm or less (B1 in FIG. 6). In this case, the organic supramolecular domain 320 may be aligned in the first direction D1. The distance D between the guide patterns 200′ may mean the width of the trench 250.

FIG. 5D is a perspective view illustrating the organic-inorganic pattern manufactured according to another embodiments.

Referring to FIGS. 5D and 6, the organic-inorganic pattern 350 may be formed between the guide patterns 200′. The organic-inorganic pattern 350 may include the single organic supramolecular domain 320. The formation of the organic-inorganic pattern 350 may be performed by the same method as described above with reference to FIGS. 5A to 5C. However, the distance D between the guide patterns 200′ may be more than 0 μm and 2 μm or less and the heights H1 of the guide patterns 200′ may be more than 0 μm and 0.7 μm or less (B2 in FIG. 6). In this case, the organic supramolecular structures 310A, 310B, 310C, and 310D may be aligned in the second direction D2. According to embodiments, the alignment directions of the organic supramolecular structures 310A, 310B, 310C, and 310D may be controlled by adjusting the distance D between the guide patterns 200′ and the heights H1 of the guide patterns 200′.

FIG. 5E is a perspective view illustrating the organic-inorganic pattern manufactured according to another embodiments.

Referring to FIGS. 5E and 6, the organic-inorganic pattern 350 may be formed between the guide patterns 200′. The formation of the organic-inorganic pattern 350 may be performed by the same method as described above with reference to FIGS. 5A to 5C. However, the distance D between the guide patterns 200′ may be more than 2 μm and 12 μm or less and the heights H1 of the guide patterns 200 may be more than 0 μm and 0.35 μm or less. Alternatively, the distance D between the guide patterns 200′ may be more than 9 μm and 12 μm or less and the heights H1 of the guide patterns 200 may be more than 0.35 μm and 0.7 μm or less (B3 in FIG. 6). After the annealing process, the organic-inorganic pattern 350 may include the randomly arranged organic supramolecular domains 320A, 320B, 320C, and 320D.

As another example, when the heights H1 of the guide patterns 200 are more than 0.7 μm and when the heights H1 of the guide patterns 200 are more than 0.35 μm and 0.7 μm or less and the distance D between the guide patterns 200′ is more than 4 μm and 9 μm or less (B4 in FIG. 6), the organic-inorganic pattern 350 may not be formed.

Hereinafter, the method for forming the organic-inorganic pattern according to an embodiment of the inventive concept and the observation result will be described in more detail with reference to Experimental examples of the present disclosure.

### Experimental Examples 1-1 to 1-3

Secondary sputtering lithography process using gold (Au) was performed to form guide patterns. Each of the guide patterns has the width of 20 nm and the height of 250 nm.

Dendrimer molecules represented by formula 1 were prepared as organic supramolecules. The dendrimer molecules were added to chloroform solvent to prepare an organic solution. The dendrimer molecules were self-assembled to form dendrimer domains. The content ratio of the dendrimer molecules in the organic solution was as shown in Table 1 below.

The organic solution was spin-coated between the guide patterns on the substrate to manufacture an organic-inorganic pattern. The organic-inorganic pattern was heated to the temperature of at least 95° C., and then cooled to room temperature (25° C.) at the cooling rate of 1° C.

Table 1 shows the content ratio of dendrimer molecules in the organic solution, used in the formation process of the organic-inorganic pattern in Experimental examples 1-1 to 1-3, and the height of the organic-inorganic pattern with respect to the height of the guide patterns.

TABLE 1

| | Experimental | Experimental | Experimental |
|---|---|---|---|
| | example 1-1 | example 1-2 | example 1-3 |
| The content ratio of | 1 | 2 | 4 |
| dendrimer molecules in | | | |
| the organic solution (wt %) | | | |
| The height of the organic- | 120 | 250 | 400 |
| inorganic film (nm) | | | |
| The height of the guide | 250 | 250 | 250 |
| patterns (nm) | | | |
| The height of the organic- | 0.48 | 1 | 1.6 |
| inorganic film/The height | | | |
| of the guide patterns | | | |

### Comparative Examples 1-1 to 1-7

A trench was formed in a silicone substrate to form guide patterns. The distance between the guide patterns and the height of the guide patterns were as shown in Table 2.

Dendrimer molecules represented by formula 1 were prepared. The dendrimer molecules were self-assembled to form dendrimer domains. The dendrimer domains were added to chloroform solvent to prepare an organic solution. The content ratio of the dendrimer molecules in the organic solution was 2 wt %.

The organic solution was spin-coated between the guide patterns on the substrate to manufacture an organic-inorganic pattern. The organic-inorganic pattern was heated to the temperature of at least 95° C., and then cooled to room temperature (25° C.) at the cooling rate of 1° C.

### Experimental Examples 2-1 to 2-8

Guide patterns and an organic-inorganic pattern were formed in the same manner as in Comparative example 1-1. However, the guide patterns had the distances between themselves and the heights as shown in Table 2. The organic-inorganic pattern was heated to the temperature of at least 95° C., and then cooled to room temperature (25° C.) at the cooling rate of 1° C.

Table 2 shows the distances between the guide patterns and the height of the guide patterns, used in the formation process of the organic-inorganic pattern in Comparative examples 1-1 to 1-7 and Experimental examples 2-1 to 2-8.

TABLE 2

| | The distance | The height |
|---|---|---|
| | between the | of the guide |
| | guide patterns (μm) | patterns (nm) |
| Experimental example 2-1 | 1.5 | 0.2 |
| Experimental example 2-2 | 1.5 | 0.5 |
| Comparative example 1-1 | 1.5 | 1.0 |
| Experimental example 2-3 | 3.0 | 0.2 |
| Experimental example 2-4 | 3.0 | 0.5 |
| Comparative example 1-2 | 3.0 | 1.0 |
| Experimental example 2-5 | 5.0 | 0.2 |
| Comparative example 1-3 | 5.0 | 0.5 |
| Comparative example 1-4 | 5.0 | 1.0 |
| Experimental example 2-6 | 7.0 | 0.2 |
| Comparative example 1-5 | 7.0 | 0.5 |
| Comparative example 1-6 | 7.0 | 1.0 |
| Experimental example 2-7 | 10.0 | 0.2 |
| Experimental example 2-8 | 10.0 | 0.5 |
| Comparative example 1-7 | 10.0 | 1.0 |

Table 3 shows the result of observing the organic-inorganic pattern 350 manufactured according to Experimental examples 1-1 to 1-3. The observation of the organic-inorganic pattern 350 was performed by using polarized optical microscopy (POM), atomic force microscopy (AFM), and gracing incidence small angle X-ray scattering (GI-SAXS) method.

TABLE 3

| | The height of the | |
|---|---|---|
| | organic-inorganic | |
| | film/The height of | The alignment directions of the |
| | the guide patterns | dendrimer domains after annealing |
| Experimental | 0.48 | Aligned in a direction parallel to |
| example 1-1 | | the guide patterns |
| Experimental | 1 | Aligned in a direction perpendicular |
| example 1-2 | | to the guide patterns |
| Experimental | 1.6 | Not aligned (random arrangement) |
| example 1-3 | | |

Referring to Table 3 in conjunction with FIGS. 2C, 3B and 4B, the formation of the single organic supramolecular domain 320 and the alignment direction may be determined by the ratio of the height H2 of the organic-inorganic film to the height H1 of the guide patterns 200.

Table 4 shows the result of observing the formation of the organic-inorganic pattern formed according to Comparative examples 1-1 to 1-7 and Experimental examples 2-1 to 2-8, and the alignment of the organic supramolecular structures (dendrimer structures) in the organic-inorganic pattern. In Table 4, “perpendicular alignment” means that the dendrimer structures are aligned in the direction (the second direction) perpendicular to the major axes of the guide patterns in a plan view, and “parallel alignment” means that the dendrimer structures are aligned in the direction (the first direction) parallel to the major axes of the guide patterns. The observation of the organic-inorganic pattern was performed by using polarized optical microscopy (POM) and atomic force microscopy (AFM).

TABLE 4

| | The alignment of the organic |
|---|---|
| | supramolecular domains in |
| | the organic-inorganic pattern |
| Experimental example 2-1 | Perpendicular alignment |
| Experimental example 2-2 | Perpendicular alignment |
| Comparative example 1-1 | The organic-inorganic pattern not formed. |
| Experimental example 2-3 | Random arrangement |
| Experimental example 2-4 | Parallel alignment |
| Comparative example 1-2 | The organic-inorganic pattern not formed. |
| Experimental example 2-5 | Random arrangement |
| Comparative example 1-3 | The organic-inorganic pattern not formed. |
| Comparative example 1-4 | The organic-inorganic pattern not formed. |
| Experimental example 2-6 | Random arrangement |
| Comparative example 1-5 | The organic-inorganic pattern not formed. |
| Comparative example 1-6 | The organic-inorganic pattern not formed. |
| Experimental example 2-7 | Random arrangement |
| Experimental example 2-8 | Random arrangement |
| Comparative example 1-7 | The organic-inorganic pattern not formed. |

Referring to Table 4 in conjunction with FIGS. 5C, 5D, 5E, and 6, in the case of Comparative examples 1-1 to 1-7, due to dewetting, the organic-inorganic pattern 350 was separated from the substrate 100 so that the organic-inorganic pattern 350 was not formed. In the case of Experimental example 2-4, the single organic supramolecular domain 320 was formed as described with reference to FIG. 5C. Herein, the organic supramolecular structures 310A, 310B, 310C, and 310D were aligned in the direction (the first direction D1) parallel to the major axes of the guide patterns 200′. In the case of Experimental examples 2-1 and 2-2, the single organic supramolecular domain 320 was observed. The organic supramolecular structures 310A, 310B, 310C, and 310D of the single organic supramolecular domain 320 were aligned in the direction (the second direction D2) perpendicular to the major axes of the guide patterns 200′. In the case of Experimental examples 2-3, 2-5, 2-6, 2-7 and 2-8 as described with reference to FIG. 5D, the organic supramolecular structures 310A, 310B, 310C, and 310D were not aligned in one direction. The organic supramolecular domains 320A, 320B, 320C, and 320D may be randomly arranged. According to embodiments, the formation of the single organic supramolecular domain 320 and the alignment direction may be controlled by adjusting the distance D between the guide patterns 200′ and the heights H1 of the guide patterns 200′.

The method of forming the organic-inorganic pattern 350 according to embodiments may be applied to the manufacture of field effect transistors, photovoltaic devices, organic opto-electronic devices, and the like. In addition, the method of forming the organic-inorganic pattern 350 according to embodiments may be applied to the manufacture of a photonic crystal or a porous membrane. However, the method of forming the organic-inorganic pattern 350 of embodiments may be applied to various fields not limited thereto.

According to the embodiments of the inventive concept, the organic supramolecular structures may be aligned in one direction by the annealing process. Therefore, the organic-inorganic pattern may include a large area single domain. By using the guide patterns, the alignment direction of the organic supramolecular structures may be controlled.

While the present disclosure has been described in detail with reference to preferable embodiments, the present disclosure is not limited to the above-described embodiments, and various changes and modifications may be made by those skilled in the art within the technical idea and scope of the invention.

What is claimed is:

1. A method of forming a pattern, comprising:
forming guide patterns on a substrate, wherein a trench is provided between the guide patterns;
forming an organic-inorganic pattern comprising organic supramolecular structures in the trench; and
annealing the organic-inorganic pattern to align the organic supramolecular structures in parallel with one direction.

2. The method of claim 1, wherein the organic supramolecular structures, before the annealing the organic-inorganic pattern, comprises:
a first organic supramolecular structure arranged in parallel with a first direction; and
a second organic supramolecular structure arranged in parallel with a second direction.

3. The method of claim 2, wherein the align the organic supramolecular structures in parallel with the one direction comprises arranging the second organic supramolecular structure in parallel with the first direction.

4. The method of claim 1, wherein the guide patterns extend in parallel with the one direction.

5. The pattern forming method of claim 4, wherein a height of the organic-inorganic pattern is 0.1 nm to 1 μm, and the height of the organic-inorganic pattern is at least 0.001 times and less than 1 times higher than a height of the guide patterns.

6. The method of claim 1, wherein the organic supramolecular structures comprise dendrimer molecules.

7. The method of claim 1, wherein the guide patterns extend in parallel with other direction, and the other direction is perpendicular to the one direction.

8. The method of claim 7, wherein a height of the organic-inorganic pattern is 1 times to 1.5 times higher than a height of the guide patterns.

9. The method of claim 1, wherein the guide patterns comprise a material different from the substrate, and the trench exposes un upper surface of the substrate.

10. The method of claim 1, wherein the forming guide patterns comprises removing a part of the substrate, thereby forming trenches, and the guide patterns comprise the same material as the substrate.

11. The method of claim 1, wherein the annealing the organic-inorganic pattern comprises:
thermally treating the organic-inorganic pattern under conditions same temperature or higher temperature than an isotropic phase transition temperature; and
cooling the organic-inorganic pattern to room temperature.

12. The method of claim 1, wherein the forming the organic-inorganic pattern comprises:
preparing an organic solution comprising dendrimer molecules; and
applying the organic solution into the trench.
